(19) United States
(12) Patent Application Publication
(10) Pub. No.: US 2012/0235259 A1
(43) Pub. Date: Sep. 20, 2012

(54) SEMICONDUCTOR PACKAGE AND METHOD OF FABRICATING THE SAME

(75) Inventors: Hao-Ju Fang, Taichung (TW); Hsin-Lung Chung, Taichung (TW); Cho-Hsin Chang, Taichung Hsien (TW); Tsung-Hsien Tsai, Taichung (TW)

(73) Assignee: SILICONWARE PRECISION INDUSTRIES CO., LTD., Tantzu (TW)

(21) Appl. No.: 13/242,182

(22) Filed: Sep. 23, 2011

(30) Foreign Application Priority Data
Mar. 18, 2011 (TW) 100109271

(51) Int. Cl. H01L 31/0203; H01L 31/18

(52) U.S. Cl. 257/428; 438/66; 438/28; 257/E31.117

(57) ABSTRACT

A semiconductor package and a method of fabricating the same. The semiconductor package includes: a substrate having a plurality of semiconductor components disposed thereon; an encapsulant covering the substrate and the semiconductor components; and a metal layer formed on the exposed surfaces of the encapsulant, wherein the encapsulant is formed with a trench for dividing into a plurality of package units on the substrate to allow each of the package units to have at least one of the semiconductor components, and the metal layer is formed in the trench to encompass the encapsulant on the periphery of the semiconductor components, thereby preventing interference of electromagnetic waves between the semiconductor components.

### BACKGROUND OF THE INVENTION

1. Field of the Invention

The present invention relates to semiconductor packages and methods of fabricating the same, and more particularly, to a semiconductor package that prevents interference of electromagnetic waves between the internal electronic components, and a method of fabricating the same.

2. Description of Related Art

Along with the development of semiconductor technology, semiconductor products with different package types have been developed. In order to improve the electrical performance of the semiconductor products, various semiconductor products are manufactured with a shielding function that prevents the generation of electromagnetic interference (EMI), as disclosed by U.S. Pat. No. 5,557,142.

U.S. Pat. No. 7,125,744B2 discloses a method of manufacturing a radio frequency (RF) module which can prevent the EMI. As shown in FIGS. 1A and 1B, U.S. Pat. No. 7,125,744B2 discloses an RF module 1 that comprises a plurality of semiconductor components 11a and 11b electrically connected to a substrate 10, and an encapsulant 12 such as an epoxy resin encapsulating the semiconductor components 11a and 11b and the substrate 10. A metal foil 13 covers the encapsulant 12. The semiconductor components 11a and 11b and the substrate 10 are protected by the encapsulant 12 such that external moisture or contaminants cannot damage the RF module 1. The metal foil 13 protects the semiconductor components 11a and 11b from the EMI.

U.S. Pat. No. 7,701,040B2 discloses a package having a plurality of modules stacked on one another. As shown in FIG. 2, U.S. Pat. No. 7,701,040B2 discloses an RF module 2 that is covered by a shielding layer 23 such that the EMI may not occur among the RF module 2 and other modules.

Although the conventional RF modules 1 and 2 can achieve an EMI shielding effect by covering a metal material around the periphery of the RF modules 1 and 2, the EMI between the semiconductor components 11a and 11b inside the RF modules 1 can not be avoid such that an abnormal signal may easily occur.

Therefore, it is imperative to provide a semiconductor package capable of preventing interference of electromagnetic waves between the electronic components inside the RF modules.

### SUMMARY OF THE INVENTION

Accordingly, the present invention provides a semiconductor package, which comprises: a substrate having a first surface and a second surface opposing the first surface; a plurality of semiconductor components mounted on and electrically connected to the substrate; an encapsulant formed on the first surface of the substrate for encapsulating the semiconductor components; and a metal layer formed on exposed surfaces of the encapsulant and the substrate; wherein the encapsulant is formed with at least a trench for dividing the encapsulant into a plurality of package units on the substrate in a manner that each of the package units has at least one of the semiconductor component, and also the metal layer is formed in the at least a trench to cover the package units, and allow the second surface of the substrate to be exposed from the metal layer.

As the described above, through the design of the trench, the substrate of the semiconductor package of the present invention is divided into a plurality of package units so that each of the package units is covered by the metal layer, thereby preventing interference of electromagnetic waves between the semiconductor components.

The present invention further provides a method of fabricating the semiconductor package as described above.

### BRIEF DESCRIPTION OF DRAWINGS

FIG. 1A is a perspective view of an RF module according to the prior art;

FIG. 1B is a cross-sectional view of the RF module of FIG. 1A;

FIG. 2 is a cross-sectional view of a package having a plurality of modules stacked on one another according to the prior art; and

FIGS. 3A to 3E are cross-sectional views showing a method of fabricating a semiconductor package according to an embodiment of the present invention, wherein FIG. 3A′ is another embodiment of FIG. 3A, and FIG. 3D′ is a perspective view of FIG. 3D.

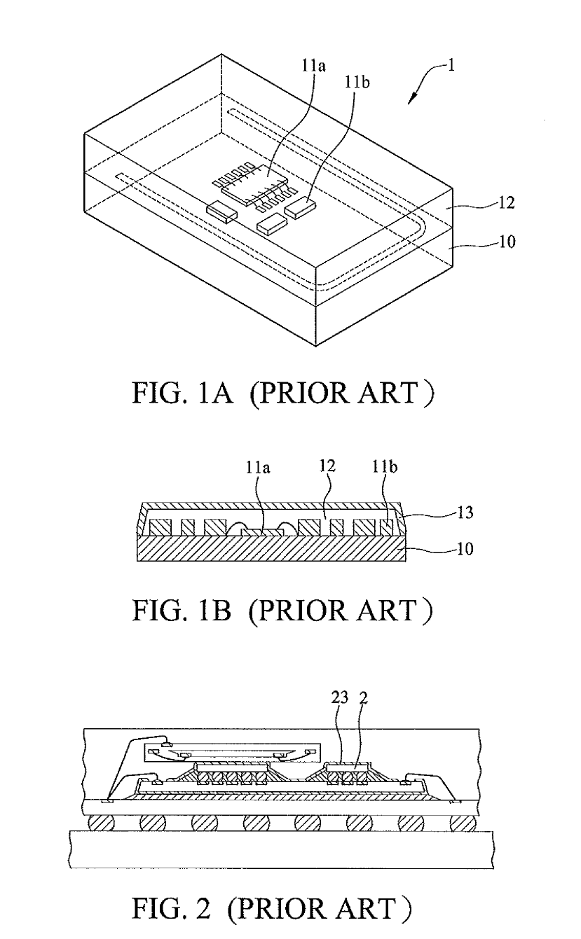

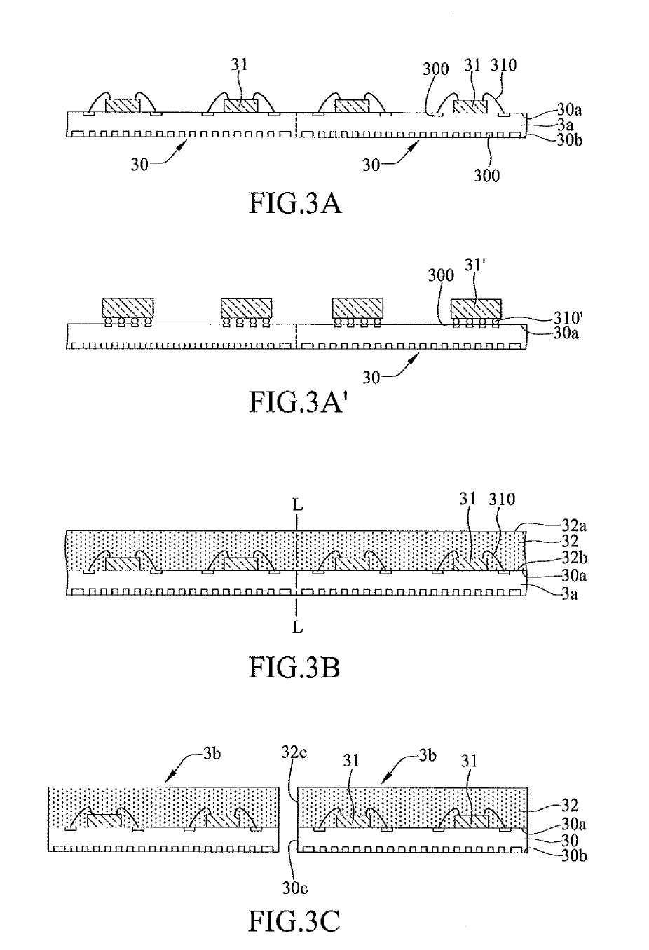

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “on,” “above,” “below,” “one,” “two,” “bottom,” “top,” “higher,” “lower,” “upper,” “over,” and “under,” etc. are merely for illustrative purpose and should not be construed to limit the scope of the present invention.

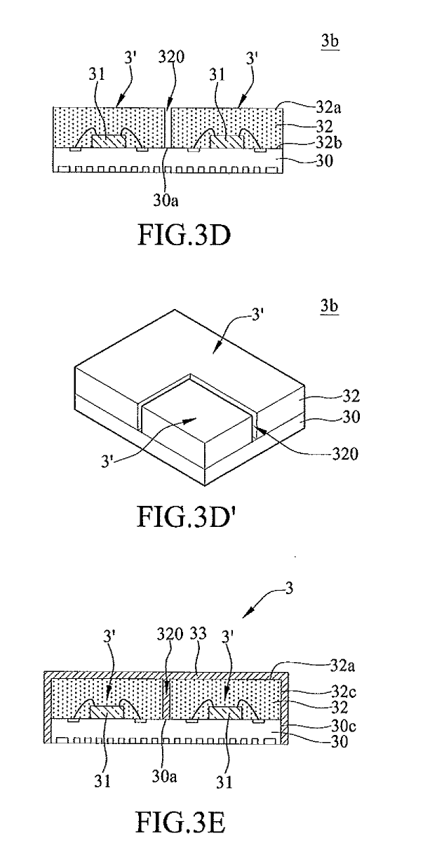

FIGS. 3A to 3E show a method of fabricating a semiconductor package according to an embodiment of the present invention. In the embodiment, a semiconductor package 3 is a device capable of generating electromagnetic waves. In an embodiment of the present invention, the semiconductor package 3 is an RF module.

Referring to FIGS. 3A and 3A′, a carrier 3a having a plurality of substrate units 30 defined by dashed lines is provided, wherein each of the substrate units 30 has an upper surface 30a defined as a first surface and a lower surface 30b defined as a second surface opposite to the upper surface 30a. Further, a plurality of semiconductor components 31 are mounted on the carrier 3a. In other words, the semiconductor components 31 are disposed on the upper surface 30a of the plurality of the substrate units 30.

Both the upper surface 30a and the lower surface 30b of each of the substrate units 30 have a plurality of conductive pads 300.

The semiconductor components 31 may be an RF chip, a Bluetooth chip or a wireless fidelity (Wi-Fi) chip.

Referring to FIG. 3A, the semiconductor components 31 may be electrically connected to conductive pads 300 on the upper surface 30a of the substrate units 30 through wiring bonding such as bonding wires 310. Alternatively, referring to FIG. 3A′, the semiconductor components 31′ may be electrically connected, in a flip-chip manner, to the conductive pads 300 on the upper surface 30a of the substrate units 30 through solder bumps 310′.

As shown in FIG. 3B, the upper surface 30a of the carrier 3a (or the substrate units 30) and each of the semiconductor components 31 including the bonding wires 310 are covered by an encapsulant 32.

The encapsulant 32 has an exposed top surface 32a and a bottom surface 32b bonded to the upper surface 30a of the substrate units 30.

Referring to FIG. 3C, the encapsulant 32 and the carrier 3a are cut along a predetermined cutting line L (as shown in FIG. 3B) of the edges of each of the substrate units 30 so as to obtain a plurality of separate pre-formed packages 3b. Each of the pre-formed packages 3b comprises one of the plurality of substrate units 30 having side surfaces 30e, the upper surface 30a and the lower surface 30b, the plurality of semiconductor components 31 mounted on the upper surface 30a of each of the substrate units 30, and the encapsulant 32 covering the upper surface 30a of substrate units 30 and each of the semiconductor components 31, wherein the cut encapsulant 32 has side surfaces 32c.

Referring to FIGS. 3D and 3D′, a trench 320 is formed in the encapsulant 32 of the pre-formed packages 3b by laser burning or mechanical cutting such as blade cutting for dividing into a plurality of package units 3′ on the upper surface 30a of substrate units 30 to allow each of the package units 3′ to have only one semiconductor component 31, but the package units 3′ also can be configured with electronic components without an effect of EMI.

In this embodiment, the trench 320 penetrates the encapsulant 32 for connecting the top surface 32a of the encapsulant 32 to the upper surface 30a of the substrate units 30.

Furthermore, in this embodiment, one of the semiconductor components 31 is a Bluetooth chip and another semiconductor component 31 is a Wi-Fi chip.

Referring to FIG. 3E, a metal layer 33 is formed in the trench 320, the top surface 32a and side surfaces 32c of the encapsulant 32, the side surfaces 30c of the substrate units 30 and exposed upper surface 30a of the substrate units 30 by chemical deposition such as sputtering to cover each of the package units 3′, and allows the second surface 30b of each of the substrate units 30 to be exposed from the metal layer 33, thereby forming a semiconductor package 3. Therein, the metal layer 33 is for EMI shielding to prevent interference of electromagnetic waves between each of the semiconductor components 31. In addition, the metal layer 33 may be formed by a coating process or a solder reflow process.

In this embodiment, the interference of signals between the Bluetooth chip and the Wi-Fi chip are shielded by the metal layer 33.

The metal layer 33 can be made of such as Cu, Ni, Fe, Al, SUS (stainless steel), etc.

According to the semiconductor package 3 and the method of fabricating the same of the present invention, through the design of the trench 320, the semiconductor package 3 is divided into a plurality of package units 3′ so that each of the package units are covered by the metal layer 33, thereby preventing interference of electromagnetic waves between each of the semiconductor components 31 of the semiconductor package 3.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a substrate having a first surface and a second surface opposing the first surface;
a plurality of semiconductor components mounted on and electrically connected to the first surface of the substrate;
an encapsulant formed on the first surface of the substrate for encapsulating the semiconductor components, wherein the encapsulant is formed with at least a trench for dividing the encapsulant into a plurality of package units on the substrate in a manner that each of the package units has at least one of the semiconductor components; and
a metal layer formed on the encapsulant and the substrate and in the at least a trench, wherein the metal layer is further formed in the trench to cover each of the package units.

2. The semiconductor package of claim 1, wherein the semiconductor package is a radio frequency (RF) module.

3. The semiconductor package of claim 1, wherein the semiconductor package is an RF chip.

4. The semiconductor package of claim 3, wherein the RF chip is a Bluetooth chip or a wireless fidelity (Wi-Fi) chip.

5. The semiconductor package of claim 1, wherein the encapsulant has an exposed top surface, side surfaces and a bottom surface bonded to the first surface of the substrate, and the trench penetrates the encapsulant for connecting the top surface of the encapsulant to the first surface of the substrate.

6. The semiconductor package of claim 5, wherein the metal layer is formed on the top surface and side surfaces of the encapsulant.

7. The semiconductor package of claim 1, wherein the metal layer is a material selected from the group consisting of Cu, Ni, Fe, Al and SUS (stainless steel).

8. A method of fabricating a semiconductor package, comprising the steps of:
preparing a pre-formed package, the pre-formed package comprising:
a substrate having a first surface and a second surface opposing the first surface;
a plurality of semiconductor components mounted and electrically connected to the first surface of the substrate; and
an encapsulant covering the first surface of the substrate and the semiconductor components;
forming a trench in the encapsulant of the pre-formed package for dividing into a plurality of package units on the substrate to allow each of the package units to have at least one of the semiconductor components; and
forming a metal layer on the encapsulant and the substrate, wherein the metal layer is further formed in the trench to cover each of the package units.

9. The method of claim 8, wherein the semiconductor package is an RF module.

10. The method of claim 8, wherein the pre-formed package is made by:
providing a carrier;
disposing the semiconductor components on the carrier;
covering the carrier with an encapsulant to cover the semiconductor components; and
cutting the encapsulant and the carrier so as to obtain a plurality of separate pre-formed packages, wherein the cut carrier is the substrate of the pre-formed package.

11. The method of claim 8, wherein the semiconductor components are RF chips.

12. The method of claim 11, wherein the RF chips are Bluetooth chips or Wi-Fi chips.

13. The method of claim 8, wherein the encapsulant has an exposed top surface, side surfaces and a bottom surface bonded to the first surface of the substrate, and the trench penetrates the encapsulant for connecting the top surface of the encapsulant to the first surface of the substrate.

14. The method of claim 13, wherein the metal layer is formed on all exposed surfaces of the encapsulant.

15. The method of claim 8, wherein the trench is formed by laser or mechanical cutting.

16. The method of claim 8, wherein the metal layer is a material selected from the group consisting of Cu, Ni, Fe, Al and SUS.
